(19) United States
(12) Patent Application Publication
(10) Pub. No.: US 2009/0260679 A1
(43) Pub. Date: Oct. 22, 2009

(54) PHOTOVOLTAIC DEVICE

(75) Inventors: HAI-LIN SUN, Beijing (CN); KAI-LI JIANG, Beijing (CN); QUN-QING LI, Beijing (CN); SHOU-SHAN FAN, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: TSINGHUA UNIVERSITY, Beijing (CN); HON HAI PRECISION INDUSTRY CO., LTD., Tu-Cheng (TW)

(21) Appl. No.: 12/339,379

(22) Filed: Dec. 19, 2008

(30) Foreign Application Priority Data
Apr. 18, 2008 (CN) 200810066749.0

(51) Int. Cl. H01L 31/00

(52) U.S. Cl. 136/255

(57) ABSTRACT

A photovoltaic device includes a substrate, a doped layer, a first electrode and a second electrode. The substrate has a plurality of cavities defined therein. The doped layer is in contact the substrate. The first electrode including a carbon nanotube composite material is adjacent to the substrate. The second electrode is attached to the substrate.

### BACKGROUND

1. Technical Field

The invention relates to energy conversion devices, and particularly to a photovoltaic device.

2. Description of Related Art

Currently, solar energy is considered a renewable and clean alternative energy source. Solar energy is generally produced by photovoltaic cells, also known as solar cells. The solar cell is a device that converts light into electrical energy using the photoelectric effect.

Generally, the solar cell includes a large-area p-n junction made from silicon. Silicon employed in the solar cell can be single crystal silicon or polycrystalline silicon. Referring to FIG. 4, a conventional solar cell 30 according to the prior art generally includes a silicon substrate 32, a doped silicon layer 34, a front electrode 36, and a rear electrode 38. The doped silicon layer 34 is in contact with the silicon substrate 32 to form a p-n junction. The front electrode 36 is disposed on and electrically connected to the doped silicon layer 34. The rear electrode 38 is disposed on and electrically connected to, e.g. via ohmic contact, the silicon substrate 32. In use, the electrodes 36, 38 are connected to an external load. Current will be generated and flow in one direction across the p-n junction by the action of the electric field if light strikes the solar cell 30.

Generally, the electrodes 36, 38 are made of conductive metals, such as aluminum (Al), silver (Ag) or copper (Cu), which are usually not transparent to light. Therefore, the electrode 36, 38, in particular, the front electrode 36 is fabricated in a finger-shape or a comb-shape to increase amount of incoming light that can pass by the electrode. Moreover, in order to enhance photoelectric conversion efficiency, transparent conductive material, e.g. indium tin oxide (ITO), may instead be selected to form the front electrode 36. However, ITO material has drawbacks, for example, ITO is known not to be chemically and mechanically durable, and as having uneven distribution of resistance. As a result, the durability and the photoelectric conversion efficiency are relatively low for devices using transparent conductive materials such as ITO.

What is needed, therefore, is a photovoltaic device that is more efficient and durable.

### BRIEF DESCRIPTION OF THE DRAWINGS

The components in the drawing are not necessarily drawn to scale, the emphasis instead being placed upon clearly illustrating the principles of the present invention.

FIG. 1 is a schematic lateral view showing a photovoltaic device in accordance with an exemplary embodiment.

FIG. 2 is a schematic view showing a first electrode of the photovoltaic device of FIG. 1.

FIG. 3 is a schematic view showing one portion of carbon nanotubes in a form of film according to an exemplary embodiment.

FIG. 4 is a schematic view of a conventional solar cell according to the prior art.

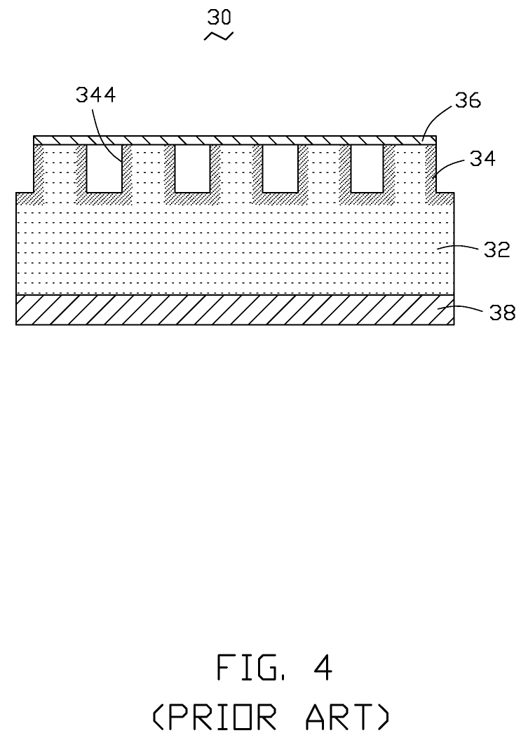

Corresponding reference characters indicate corresponding parts throughout the drawings. The exemplifications set out herein illustrate at least one embodiment of the present photovoltaic device, in one form, and such exemplifications are not to be construed as limiting the scope of the disclosure in any manner.

### DETAILED DESCRIPTION OF THE EMBODIMENT

Reference will now be made to the drawings to describe embodiments of the present photovoltaic device in detail.

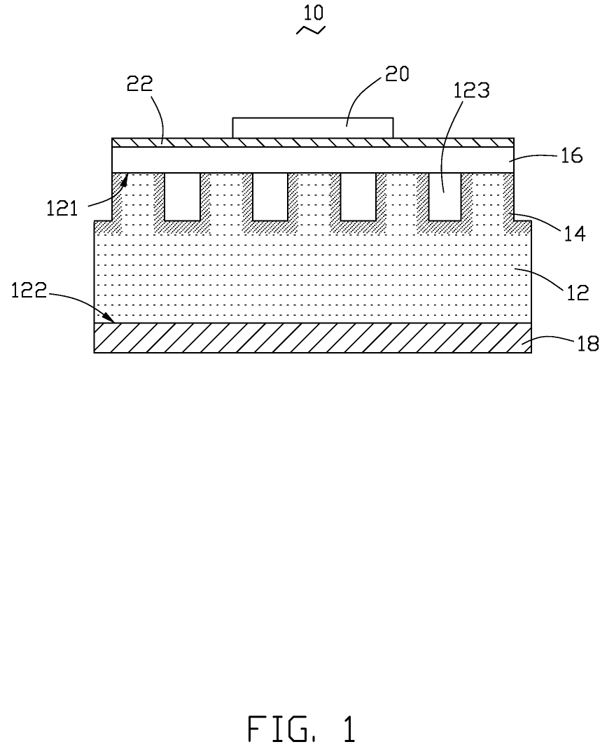

Referring to FIG. 1, a photovoltaic device 10 according to an exemplary embodiment, is shown. The photovoltaic device 10 includes a substrate 12, a doped layer 14, a first electrode 16, and a second electrode 18.

The substrate 12 can be made of single crystal silicon. In the exemplary embodiment, the substrate 12 is p-type single crystal silicon. In addition, a thickness of the substrate 12 is in a range from about 200 μm to about 300 μm. The substrate 12 has a front surface 121 and a rear surface 122, as shown in FIG. 1. The front surface 121 of the substrate 12 defines a plurality of cavities 123. That is, some portions of the front surface 121 form the cavities 123 for enhancing light collation and increasing the area of p-n junction formation. The cavities 123 are distributed evenly and are spaced from each other by a distance in a range from about 10 μm to about 30 μm. In addition, a depth of each of the cavities 123 is in a range from about 50 μm to about 70 μm. However, in other embodiments, the cavities 123 may vary in shape and dimension. While a square cross section is shown, the cross section of each of the cavities 123 can be, for example, square, trapezoidal, triangular, circular or other shapes.

The doped layer 14 is disposed on inside walls of each cavity 123. In the exemplary embodiment, the doped layer 14 is n-type silicon made by adding an abundance of dopant, such as phosphorus (P) or arsenic (As), into the substrate 12. In addition, a thickness of the doped layer 14 is in a range from about 500 nm to about 1 μm. Thus, a plurality of p-n junctions are formed where the n-type doped layer 14 and the p-type single crystal substrate 12 meet, achieving light radiation to electrical energy conversions.

The first electrode 16 is adjacent to the front surface 121 of the substrate 12. The second electrode 18 is attached to the rear surface 122 of the substrate 12. The second electrode 18 can be made of aluminum (Al), magnesium (Mg), or silver (Ag), and has a thickness ranging from 10 μm to 300 μm.

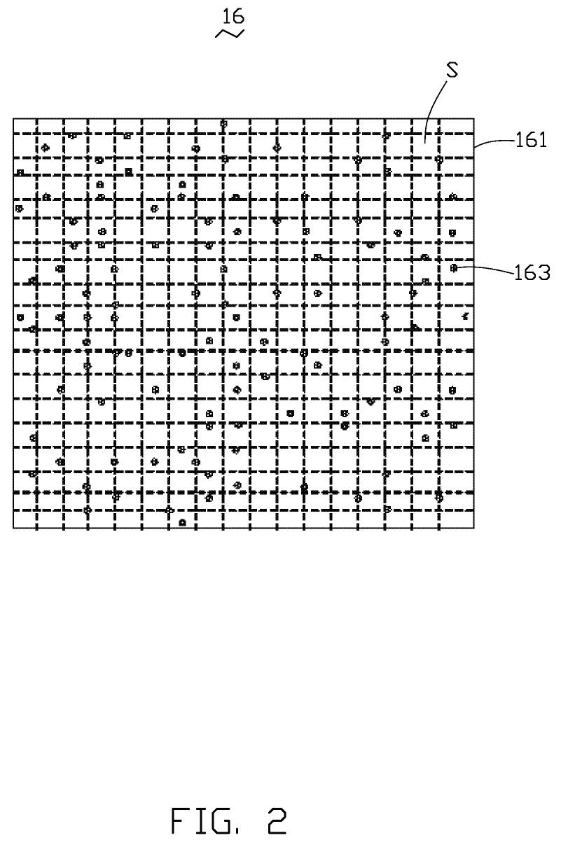

Referring to FIG. 1 and FIG. 2, the first electrode 16, which includes a carbon nanotube (CNT) composite material, is configured for collecting current generated at the p-n junctions based on photoelectric conversion. The composite material includes a plurality of CNTs 161 and a plurality of metal particles 163 dispersed in the CNTs. In the exemplary embodiment, the metal particles 163 are evenly dispersed in the CNT composite material. The metal particles 163 can be selected from the group consisting of platinum (Pt), palladium (Pd), ruthenium (Ru), silver (Ag), gold (Au), alloys and combinations thereof. An average particle diameter of the metal particles 163 is in a range from about 1 nm to about 10 nm. A percentage by mass of the metal particles 163 in the CNT composite material is in a range from about 10% to about 30%.

In the exemplary embodiment, the CNTs 161 can be selected from a group consisting of single-walled CNTs (SWCNTs), double-walled CNTs, multi-walled CNTs (MWCNTs), and combinations thereof. When the SWCNTs are employed in the first electrode 16, a diameter of each of the SWCNTs is in a range from about 0.5 nm to about 50 nm. When the double-walled CNTs are employed in the first electrode 16, a diameter of each of the double-walled CNTs is in a range from about 1.0 nm to about 50.0 nm. Alternatively, when the MWCNTs are employed in the first electrode 16, a diameter of each of the MWCNTs is in a range from about 1.5 nm to about 50.0 nm. In the exemplary embodiment, the first electrode 16 made of CNT composite material can be directly adhered on the front surface 121 of the substrate 12 due to the adhesiveness of the CNTs 161. In the exemplary embodiment, a percentage by mass of the CNTs 161 in the CNT composite material is in a range from about 70% to about 90%.

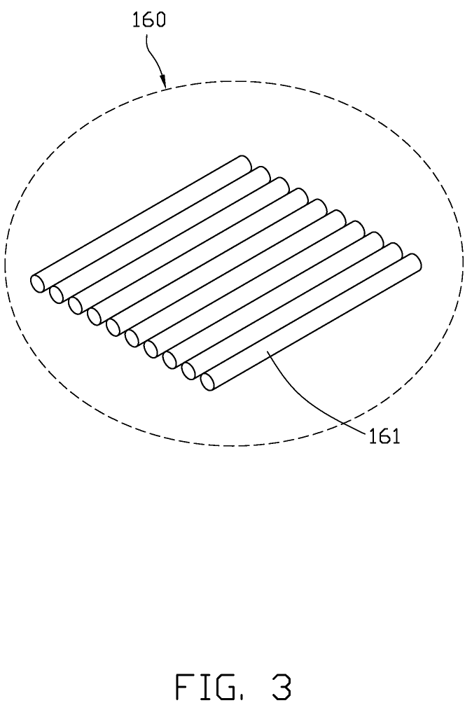

In the exemplary embodiment, the CNTs 161 can be arranged orderly or disorderly. In addition, the CNTs 161 can be in a form of at least one film, as shown in FIG. 2. The film can be fabricated by being drawn from a CNT array, which may be formed on a 4-inch silicon by vapor deposition. Referring to FIG. 3, the film includes a plurality of successively oriented CNT segments 160 joined end-to-end by van der Waals attractive force. Each CNT segment 160 comprises a plurality of CNTs substantially parallel to each other and with the same length. In the exemplary embodiment, a width of the film is in a range of about 0.01 cm to about 10.00 cm. A thickness of the film is in a range of about 10 nm to 100 μm. Referring to FIG. 2, the film defines a plurality of spaces S that allow relatively greater amount of incoming light to penetrate into the silicon substrate 12. The metal particles 163 can be dispersed on the film, as shown in FIG. 2.

In the film having ordered CNTs 161, the CNTs 161 are arranged along and parallel to a surface of the film. In addition, the CNTs 161 are oriented along one direction. Alternatively, the CNTs 161 can be oriented along different directions, e.g. two directions perpendicular to each other. In the film having disordered CNTs 161, the CNTs 161 entangle with each other or are arranged in an isotropic fashion.

In other embodiments, the CNTs 161 can be in the form of two or more stacked films. The alignment direction of CNTs 161 of two adjacent films, or sets of films, can be set at an angle α to each other. The angle α is in a range of 0<α≦90°. It is noted that the number of the films can be chosen according to practical requirements, forming different thickness of the first electrode 16. In the exemplary embodiment, there are two films set at an angle of 90 degrees, as seen in FIG. 2.

The length and width of the film is only limited by the size of the CNT array. Furthermore, the CNTs of the film, which are joined end-to-end, with the same length and arranged substantially uniform, provide the photovoltaic device 10 with a substantially uniform distribution of resistance. The spaces S defined on the film also provide the photovoltaic device 10 with better light transmission. A first electrode 16 made with CNTs has improved mechanical strength and durability by virtue of the CNTs.

In use, when light strikes on the photovoltaic device 10, one portion of incoming light passes through the spaces S and is incident into the cavities 123 while the other portion of incoming light shines on the first electrode 16. For the portion of incoming light passing through the spaces S, the light will be trapped through multiple reflections within the cavities 123. The light absorption is increased and the photovoltaic device 10 has greatly enhanced efficiency.

For the portion of incoming light shining on the first electrode 16, surface plasmons are observed on the metal particles 163 as light shines onto the surfaces of metal particles 163 of the first electrode 16. The surface plasmons can then be excited by the light and interact with the light to result in a polariton. A phenomenon of surface plasmon resonance is generated, i.e. surface plasmons are excited to be in resonance with the incoming light of a predetermined frequency. By way of the surface plasmon resonance on the metal particles 163, the incoming light again irradiates from the metal particles 163 and is incident into the cavities 123. As a result, the absorption of light for the photovoltaic device 10 is increased.

Furthermore, the photovoltaic device 10 of the exemplary embodiment can further include an anti-reflection layer 22 disposed on the first electrode 16. The anti-reflection layer 22 is configured to reduce light striking on the first electrode 16 to reflect, causing the energy conversion efficiency to be enhanced. In the exemplary embodiment, the anti-reflection layer 22 is made of titanium dioxide or zinc aluminum oxide.

In exemplary embodiment, the photovoltaic device 10 further includes at least one third electrode 20 electrically connected to the first electrode 16 for collecting current flowing through the first electrode 16.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A photovoltaic device, comprising:
a substrate having a plurality of cavities defined therein;
a doped layer in contact the substrate;
a first electrode comprising a carbon nanotube composite material adjacent to the substrate; and
a second electrode attached to the substrate.

2. The photovoltaic device as claimed in claim 1, wherein the substrate comprises p-type silicon.

3. The photovoltaic device as claimed in claim 1, wherein a thickness of the substrate is in a range from about 200 μm to about 300 μm.

4. The photovoltaic device as claimed in claim 1, wherein the cavities are spaced from each other by a distance in a range from about 10 μm to about 30 μm.

5. The photovoltaic device as claimed in claim 1, wherein a depth of each of the cavities is in a range from about 50 μm to about 70 μm.

6. The photovoltaic device as claimed in claim 1, wherein the doped layer comprises n-type silicon.

7. The photovoltaic device as claimed in claim 1, wherein the carbon nanotube composite material comprises of a plurality of carbon nanotubes and a plurality of metal particles.

8. The photovoltaic device as claimed in claim 7, wherein each metal particle comprises of a material that is selected from the group consisting of platinum, palladium, ruthenium, silver, gold, and any alloy thereof.

9. The photovoltaic device as claimed in claim 7, wherein the metal particles have an average particle diameter in a range from about 1 nm to about 10 nm.

10. The photovoltaic device as claimed in claim 7, wherein the carbon nanotubes are arranged in a disorderly fashion.

11. The photovoltaic device as claimed in claim 7, wherein at least a portion of the carbon nanotubes are in a form of at least one film.

12. The photovoltaic device as claimed in claim 11, wherein the at least one film comprises of a plurality of successively oriented carbon nanotube segments joined end-to-end by van der Waals attractive force.

13. The photovoltaic device as claimed in claim 12, wherein each carbon nanotube segment comprises a plurality of carbon nanotubes substantially parallel to each other and with the same length.

14. The photovoltaic device as claimed in claim 11, wherein there are two or more stacked films.

15. The photovoltaic device as claimed in claim 14, wherein the carbon nanotubes of the adjacent films are set at an angle ranging from about 0 degrees to about 90 degrees.

16. The photovoltaic device as claimed in claim 1, further comprising a third electrode electrically connected to the first electrode.

17. The photovoltaic device as claimed in claim 1, further comprising an anti-reflection layer disposed on the first electrode.

18. The photovoltaic device as claimed in claim 17, wherein the anti-reflection layer comprises of titanium dioxide or zinc aluminum oxide.
